(19) United States
(12) Patent Application Publication
(10) Pub. No.: US 2016/0295754 A1
(43) Pub. Date: Oct. 6, 2016

(54) MAGNETIC SHIELDING STRAND, METHOD OF MANUFACTURING THE SAME, AND MAGNETIC-SHIELDING BRAIDED SLEEVE AND MAGNETIC SHIELDED CABLE USING THE SAME

(71) Applicant: Hitachi Metals, Ltd., Toyko (JP)

(72) Inventors: Detian HUANG, Hitachi (JP); Masanori Kobayashi, Hitachi (JP); Takanobu Watanabe, Hitachi (JP)

(21) Appl. No.: 15/060,449

(22) Filed: Mar. 3, 2016

(30) Foreign Application Priority Data
Apr. 2, 2015 (JP) 2015-076268

(51) Int. Cl. H05K 9/00

(52) U.S. Cl. CPC H05K 9/0075; H05K 9/0098

(57) ABSTRACT

A magnetic shielding strand includes a conductor strand, and a magnetic shielding layer formed around the conductor strand. The magnetic shielding layer includes coating film layers and a magnetic powder layer sandwiched between the coating film layers. The magnetic powder layer includes a nanocrystalline soft magnetic material, and the coating film layer includes a UV curable resin coating material or a thermosetting resin coating material.

The present application is based on Japanese patent application No. 2015-076268 filed on Apr. 2, 2015, the entire contents of which are incorporated herein by reference.

### BACKGROUND OF THE INVENTION

1. Field of the Invention

The invention relates to a magnetic shielding strand used for a magnetic shield which reduces the influence of an external magnetic field which may be a source of external noise, a method of manufacturing the magnetic shielding strand, and a magnetic-shielding braided sleeve and a magnetic shielded cable using the magnetic shielding strand.

2. Description of the Related Art

Magnetic shields are used in electronic devices such as computers to reduce an influence of an external magnetic field which can be a source of external noise. The magnetic shield draws a magnetic flux, which otherwise would reach signal lines, so that the magnetic flux is bypassed, thereby reducing an influence of an external magnetic field to be a source of external noise.

For example, the followings are known as conventional magnetic shields: a ferrite core which is formed of magnetic ceramic consisting mainly of iron oxide and has a cylindrical shape or an annular shape with a hollow into which an electric wire is inserted (see e.g., JP-U-3172343(Utility Model)); and a magnetic resin layer formed around an electric wire by extrusion molding of a magnetic resin composition which is obtained by mixing magnetic powder with a base resin composition (see e.g., JP-A-2004-158328 and JP-A-H11-86641).

### SUMMARY OF THE INVENTION

The ferrite cores are however not pliable at all. Thus, if the ferrite core is attached to an end portion, etc., of an electric wire to be connected to an electronic device, etc., flexibility or flex resistance of the end portion, etc., of the electric wire is impaired and the electric wire becomes likely to be broken at, e.g., a base portion of the ferrite core due to stress concentration associated with bending, etc., of the electric wire.

The magnetic resin layer is more pliable than the ferrite core and flexibility or flex resistance of the electric wire is less likely to be impaired when using the magnetic resin layer. However, when a resin composition containing magnetic powder, etc., is extruded from an extruder, there is a possibility that a screw of the extruder is damaged by the magnetic powder and a plating on the surface of the screw comes off and is mixed as a foreign substance into the magnetic resin composition. In addition, it is necessary to replace the screw very often. Thus, it is not possible to continuously run the extruder for a long period of time, causing a problem in productivity.

It is an object of the invention to provide a magnetic shielding strand that is suited to manufacture a magnetic shielded cable that prevents the flexibility and flex resistance of an electric wire from being impaired, as well as a method of manufacturing the magnetic shielding strand, and a magnetic-shielding braided sleeve and a magnetic shielded cable using the magnetic shielding strand.

(1) According to an embodiment of the invention, a magnetic shielding strand comprises:

a conductor strand; and

a magnetic shielding layer formed around the conductor strand,

wherein the magnetic shielding layer comprises coating film layers and a magnetic powder layer sandwiched between the coating film layers.

In the above embodiment (1) of the invention, the following modifications and changes can be made.

(i) The magnetic powder layer comprises a nanocrystalline soft magnetic material, and the coating film layer comprises a UV curable resin coating material or a thermosetting resin coating material.

(ii) The magnetic shielding layer comprises a plurality of magnetic shielding layers each of which comprises the coating film layers and the magnetic powder layer sandwiched between the coating film layers.

(2) According to another embodiment of the invention, a method of manufacturing the magnetic shielding strand according to the above embodiment (1) comprises:

a first step of forming an uncured coating film layer by applying a coating material around the conductor strand;

a second step of forming the magnetic powder layer by applying magnetic powder so as to be attached to the uncured coating film layer;

a third step of forming another uncured coating film layer by applying a coating material around the magnetic powder layer; and

a fourth step of curing all the uncured coating film layers to obtain the coating film layers.

In the above embodiment (2) of the invention, the following modifications and changes can be made.

(iii) The second and third steps are repeated.

(3) According to another embodiment of the invention, a magnetic-shielding braided sleeve comprises the magnetic shielding strand according to the above embodiment (1) that is braided.
(4) According to another embodiment of the invention, a magnetic-shielding braided sleeve comprises the magnetic shielding strand according to the above embodiment (1) and spun rayon yarns that are braided.
(5) According to another embodiment of the invention, a magnetic shielded cable comprises a braided magnetic shield formed by braiding the magnetic shielding strand according to the above embodiment (1), or a served magnetic shield formed by winding the magnetic shielding strand according to the above embodiment (1).

### Effects of the Invention

According to an embodiment of the invention, a magnetic shielding strand can be provided that is suited to manufacture a magnetic shielded cable that prevents the flexibility and flex resistance of an electric wire from being impaired, as well as a method of manufacturing the magnetic shielding strand, and a magnetic-shielding braided sleeve and a magnetic shielded cable using the magnetic shielding strand.

### BRIEF DESCRIPTION OF THE DRAWINGS

Next, the present invention will be explained in more detail in conjunction with appended drawings, wherein:

FIG. 1 is a cross sectional view showing a magnetic shielding strand in a first embodiment;

FIG. 2 is a cross sectional view showing a magnetic shielding strand in a second embodiment;

FIG. 3 is a perspective view showing a magnetic-shielding braided sleeve in a third embodiment;

FIG. 4 is a perspective view showing a magnetic-shielding braided sleeve in a fourth embodiment;

FIG. 5 is a cross sectional view showing a magnetic shielded cable in a fifth embodiment;

FIG. 6 is a cross sectional view showing a magnetic shielded cable in a sixth embodiment; and

FIG. 7 is a cross sectional view showing a magnetic shielded cable in a seventh embodiment.

### DETAILED DESCRIPTION OF THE PREFERRED EMBODIMENTS

Preferred embodiments of the invention will be described below in conjunction with the appended drawings.

Firstly, a magnetic shielding strand in the first embodiment will be described.

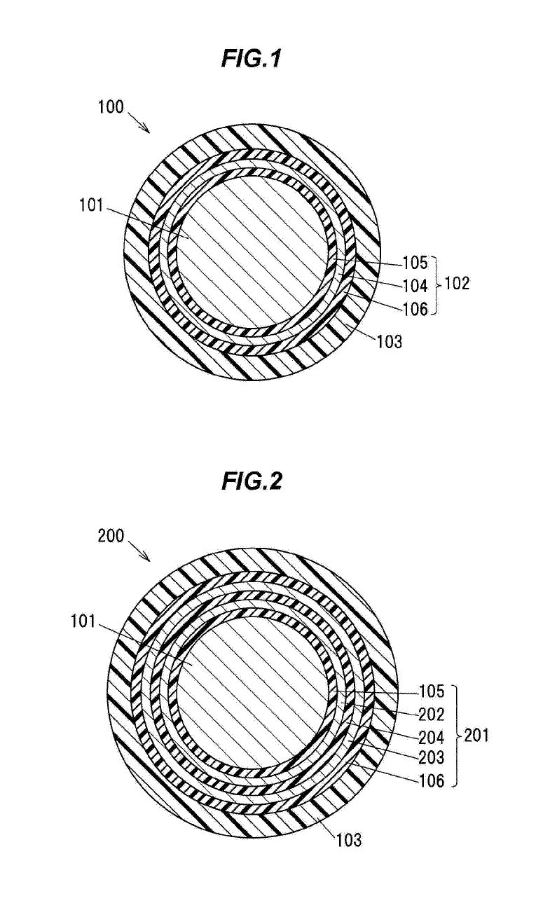

As shown in FIG. 1, a magnetic shielding strand 100 in the first embodiment is a strand to be used to form a magnetic shield (e.g., a braided magnetic shield or a served magnetic shield), and is provided with a conductor strand 101, a magnetic shielding layer 102 formed around the conductor strand 101 and a covering layer 103 formed around the magnetic shielding layer 102.

The magnetic shielding layer 102 is formed by sandwiching a single magnetic powder layer 104 between two coating film layers (an inner coating film layer 105 and an outer coating film layer 106), and serves to reduce an influence of an external magnetic field to be a source of external noise when a magnetic shield is formed using the magnetic shielding strand 100.

The magnetic shielding strand 100 is manufactured through a process including a first step of forming an uncured coating film layer (an inner uncured coating film layer) by applying a coating material around the conductor strand 101, a second step of forming the magnetic powder layer 104 by applying magnetic powder so as to be attached to the inner uncured coating film layer, a third step of forming another uncured coating film layer (an outer uncured coating film layer) by applying a coating material around the magnetic powder layer 104, and a fourth step of curing the inner and outer uncured coating film layers to obtain the inner coating film layer 105 and the outer coating film layer 106.

That is, when manufacturing the magnetic shielding strand 100, the inner uncured coating film layer, the magnetic powder layer 104 and the outer uncured coating film layer are formed sequentially on the surface of the conductor strand 101 while continuously feeding the conductor strand 101 at a predetermined feeding rate (e.g., 200 m/min), and then, the inner and outer uncured coating film layers are cured simultaneously to form the inner coating film layer 105 and the outer coating film layer 106. Therefore, it is easy to form the magnetic shielding layer 102, and it is thereby possible to mass produce the magnetic shielding strand 100 in a short period of time.

The conductor strand 101 is formed of copper or copper alloy, etc., having high conductivity and serves to reduce an influence of an external electromagnetic wave to be a cause of external noise when a magnetic shield is formed using the magnetic shielding strand 100.

The covering layer 103 is formed of an enamel coating, etc., having high scratch resistance, etc., and serves as a jacket to prevent damage, etc., on the magnetic shielding strand 100 which is caused by mutual contact between the magnetic shielding strands 100 when a magnetic shield is formed using the magnetic shielding strand 100. In this regard, the covering layer 103 does not need to be provided for the application in which damage, etc., on the magnetic shielding strand 100 is less likely to occur.

The magnetic powder layer 104 has a thickness of about not less than 5 μm and not more than 10 μm, and is preferably formed of a material having high magnetic shielding performance such as a nanocrystalline soft magnetic material (e.g., FINEMET (registered tradename) manufactured by Hitachi Metals, Ltd.).

The inner coating film layer 105 and the outer coating film layer 106 have a thickness of about not less than 5 μm and not more than 10 μm, and are preferably formed of a coating material which is highly adhesive to magnetic powder in an uncured state and is highly pliable in a cured state, such as UV curable resin coating material (e.g., urethane acrylate resin coating material, epoxy acrylate resin coating material, silicone resin coating material, silicone acrylate resin coating material or polyester acrylate resin coating material) or thermosetting resin coating material (e.g., polyurethane resin coating material).

Such a configuration allows the magnetic shielding strand 100 to have a small diameter and higher flexibility.

The magnetic powder such as FINEMET (registered tradename) has a very small cylindrical shape and can achieve the maximum magnetic shielding performance when the orientation thereof is aligned and a magnetic path for a magnetic flux is optimized. In this regard, since the magnetic shielding layer 102 is formed while continuously feeding the conductor strand 101 when manufacturing the magnetic shielding strand 100 as described above, a fictitious force during this process aligns the orientation of the magnetic powder.

The inner coating film layer 105 needs to be formed of a coating material having high adhesion to magnetic powder in the uncured state, but the outer coating film layer 106 does not necessarily need to be formed of a coating material having high adhesion to magnetic powder in the uncured state.

The reason is as follows: if the inner coating film layer 105 is not formed of a coating material having high adhesion to magnetic powder in the uncured state, the amount of the magnetic powder adhered to the inner uncured coating film layer is reduced and this may cause a decrease in the magnetic shielding performance of the magnetic shielding layer 102. On the other hand, even if the outer coating film layer 106 is not formed of a coating material having high adhesion to magnetic powder in the uncured state, the amount of the magnetic powder adhered to the inner uncured coating film layer does not change and there is no risk of degrading the magnetic shielding performance of the magnetic shielding layer 102.

However, if the outer coating film layer 106 is not formed of a coating material having high adhesion to magnetic powder in the uncured state, it may not be possible to uniformly apply a coating material to the surface of the magnetic powder layer 104 depending on the method of forming the outer coating film layer 106, and it may be difficult to sandwich the magnetic powder layer 104 by the inner coating film layer 105 and the outer coating film layer 106.

It is further preferable that the outer coating film layer 106 be formed of a coating material which has high adhesion to the inner coating film layer 105 in the cured state and can be cured at the same time as the inner coating film layer 105.

This is because, when the outer coating film layer 106 is not formed of a coating material having high adhesion to the inner coating film layer 105 in the cured state, a space may be formed between the inner coating film layer 105 and the outer coating film layer 106, causing movement of the magnetic powder in the space and uneven magnetic powder distribution in the magnetic shielding layer 102.

Meanwhile, when the outer coating film layer 106 is not formed of a coating material which can be cured at the same time as the inner coating film layer 105, it is necessary to separately cure the inner coating film layer 105 and the outer coating film layer 106. Therefore, it takes long time to form the magnetic shielding layer 102, causing a decrease in production yield of the magnetic shielding strand 100.

In contrast, when the outer coating film layer 106 is formed of a coating material which has high adhesion to the inner coating film layer 105 in the cured state, the magnetic powder is embedded between the inner coating film layer 105 and the outer coating film layer 106 which are tightly adhered to each other. Therefore, the magnetic powder distribution in the magnetic shielding layer 102 can be fixed and uneven magnetic powder distribution in the magnetic shielding layer 102 caused by bending of the magnetic shielding strand 100 can be prevented.

Next, a magnetic shielding strand in the second embodiment will be described.

As shown in FIG. 2, a magnetic shielding strand 200 in the second embodiment is a strand to be used to form a magnetic shield, and is provided with the conductor strand 101, a magnetic shielding layer 201 formed around the conductor strand 101 and the covering layer 103 formed around the magnetic shielding layer 201.

The magnetic shielding layer 201 is formed by repeatedly laminating layers so that two magnetic powder layers (an inner magnetic powder layer 202 and an outer magnetic powder layer 203) are sandwiched by three coating film layers (the inner coating film layer 105, a middle coating film layer 204 and the outer coating film layer 106).

The magnetic shielding strand 200 is manufactured through a process including a first step of forming an inner uncured coating film layer by applying a coating material around the conductor strand 101, a second step of forming the inner magnetic powder layer 202 by applying magnetic powder so as to be attached to the inner uncured coating film layer, a third step of forming another uncured coating film layer (a middle uncured coating film layer) by applying a coating material around the inner magnetic powder layer 202, a fourth step of forming the outer magnetic powder layer 203 by applying magnetic powder so as to be attached to the middle uncured coating film layer, a fifth step of forming an outer uncured coating film layer by applying a coating material around the outer magnetic powder layer 203, and a sixth step of curing the inner, middle and outer uncured coating film layers to obtain the inner coating film layer 105, the middle coating film layer 204 and the outer coating film layer 106.

That is, the magnetic shielding strand 200 is different from the magnetic shielding strand 100 only in that the magnetic shielding layer 102 is replace with the magnetic shielding layer 201 which is formed by repeating the second and third steps in manufacturing of the magnetic shielding strand 100 and thus has the inner magnetic powder layer 202 and the outer magnetic powder layer 203 sandwiched by the inner coating film layer 105, the middle coating film layer 204 and the outer coating film layer 106.

For the same reason as for the inner coating film layer 105 and the outer coating film layer 106, the middle coating film layer 204 has a thickness of about not less than 5 μm and not more than 10 μm, and is preferably formed of a coating material which is highly adhesive to magnetic powder in an uncured state and is highly pliable in a cured state, such as UV curable resin coating material or thermosetting resin coating material.

In addition, for the same reason as for the outer coating film layer 106, the middle coating film layer 204 is preferably formed of a coating material which has high adhesion to the inner coating film layer 105 and the outer coating film layer 106 in the cured state and can be cured at the same time as the inner coating film layer 105 and the outer coating film layer 106.

Next, a magnetic-shielding braided sleeve in the third embodiment will be described.

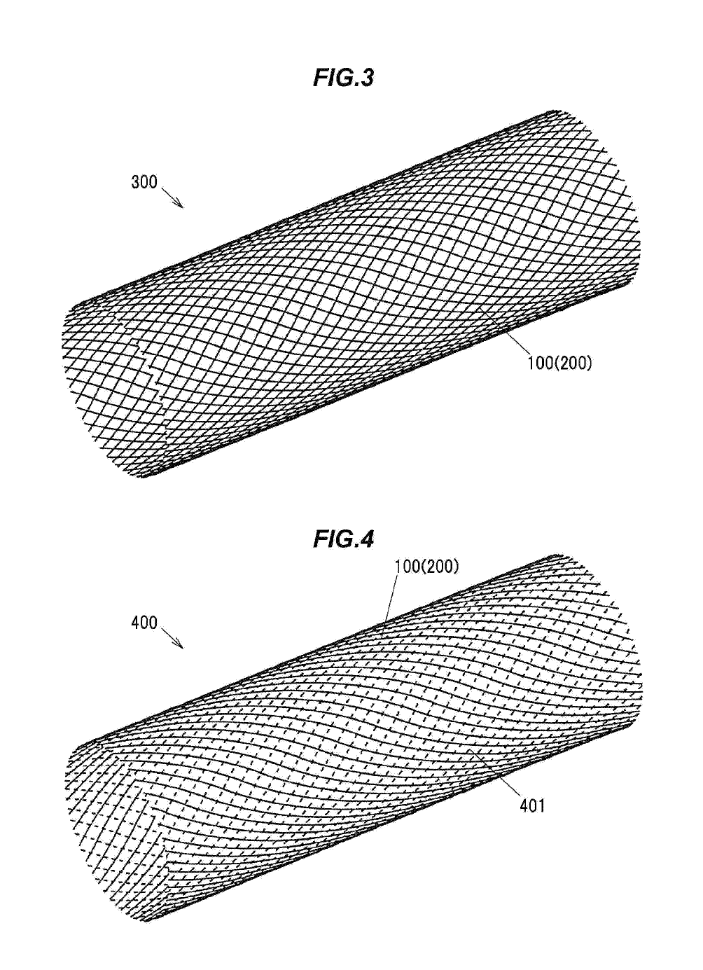

As shown in FIG. 3, a magnetic-shielding braided sleeve 300 in the third embodiment is formed by braiding the magnetic shielding strands 100 or the magnetic shielding strands 200, and is used as an outer conductor serving as a magnetic shield and also as an electromagnetic shield in, e.g., a coaxial cable.

The magnetic shielding layer 102 and the covering layer 103 can be sufficiently melted by heat of soldering (e.g., about not less than 280° C. and not more than 300° C.). Therefore, the magnetic-shielding braided sleeve 300 can be easily grounded by soldering the magnetic-shielding braided sleeve 300 to a ground terminal, etc.

The magnetic-shielding braided sleeve 300 is highly pliable. Therefore, flexibility or flex resistance of an electric wire is less likely to be impaired even when the magnetic-shielding braided sleeve 300 is applied around the electric wire and, in combination with ease of manufacturing the magnetic shielding strand, it is possible to mass produce in a short period of time.

Next, a magnetic-shielding braided sleeve in the fourth embodiment will be described.

As shown in FIG. 4, a magnetic-shielding braided sleeve 400 in the fourth embodiment is formed by braiding the magnetic shielding strands 100 (or the magnetic shielding strands 200) and spun rayon yarns 401, and is used as an outer conductor serving as a magnetic shield and also as an electromagnetic shield in, e.g., a coaxial cable.

The magnetic shielding strands 100 (or the magnetic shielding strands 200) and the spun rayon yarns 401 are braided so that one is a weft and the other is a warp, thereby preventing mutual contact between the magnetic shielding strands 100 (or the magnetic shielding strands 200).

This prevents damage, etc., on the magnetic shielding strands 100 (or the magnetic shielding strands 200) even when the covering layer 103 is not provided.

The magnetic-shielding braided sleeve 400 is highly pliable and further is less likely to be broken by fatigue due to bending or twisting, etc. Therefore, flexibility or flex resistance of an electric wire is less likely to be impaired even when the magnetic-shielding braided sleeve 400 is applied around the electric wire and, in combination with ease of manufacturing the magnetic shielding strand, it is possible to mass produce in a short period of time.

Next, a magnetic shielded cable in the fifth embodiment will be described.

As shown in FIG. 5, a magnetic shielded cable 500 in the fifth embodiment is provided with an inner conductor 501, an insulation 502 formed around the inner conductor 501, an outer conductor 503 formed around the insulation 502, and a covering body 504 formed around the outer conductor 503.

The outer conductor 503 is constructed from a braided magnetic shield formed by braiding the magnetic shielding strands 100 (or the magnetic shielding strands 200), or a served magnetic shield formed by winding the magnetic shielding strands 100 (or the magnetic shielding strands 200).

The magnetic shielded cable 500, which is provided with a braided magnetic shield or a served magnetic shield formed using the magnetic shielding strands 100 (or the magnetic shielding strands 200), can achieve magnetic shielding performance and electromagnetic shielding performance throughout the entire length without impairment in flexibility or flex resistance required for coaxial cables.

In addition to the outer conductor 503, the magnetic shielded cable 500 may also have a braided electromagnetic shield or a served electromagnetic shield formed using an electromagnetic shielding strand composed of conductors formed of copper or copper alloy, etc.

Next, a magnetic shielded cable in the sixth embodiment will be described.

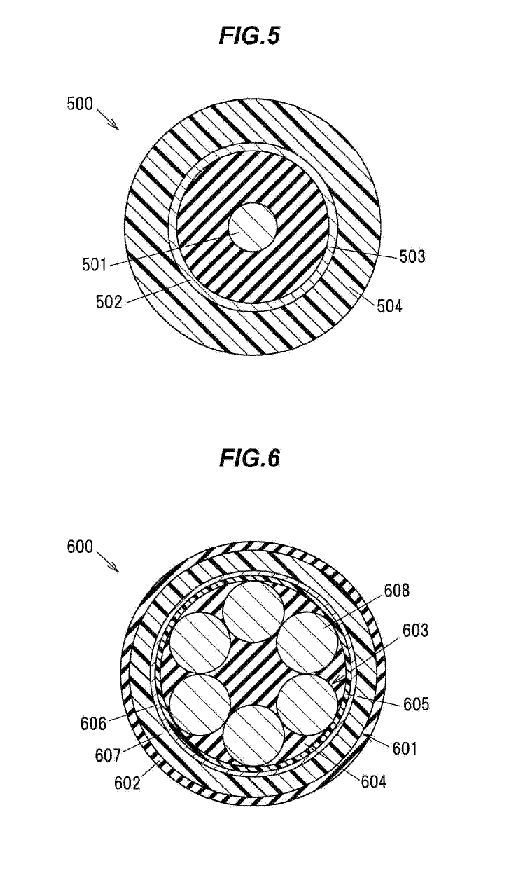

As shown in FIG. 6, a magnetic shielded cable 600 in the sixth embodiment is a cable to be wired in a moving part, and is provided with a cable core 601 and a protective film 602 formed around the cable core 601.

The cable core 601 is provided with, e.g., a twisted wire 603, a filler 604 filled in a space present on a circular cross section of the twisted wire 603, a tape 605 wound around the twisted wire 603, a shield 606 provided around the tape 605, and a sheath 607 provided around the shield 606.

The twisted wire 603 is formed by twisting plural electric wires 608 each of which is, e.g., an insulated wire having a conductor and an insulation provided therearound, or a coaxial cable having inner and outer conductors. The positions of the plural electric wires 608 are fixed by the filler 604 filled in the space present on the circular cross section of the twisted wire 603. Therefore, symmetry of the twisted wire 603 on the cross section of the cable can be maintained throughout the longitudinal direction of the cable, which allows variation in impedance to be suppressed throughout the longitudinal direction of the cable.

The tape 605 is formed of paper, a fluorine resin, a nylon resin or a material with high lubricity such as polyethylene terephthalate resin, and is wrapped around the twisted wire 603 with partial overlap. Thus, the plural electric wires 608 are less likely to unravel and the positions of the plural electric wires 608 are fixed, which allows symmetry of the twisted wire 603 on the cross section of the cable to be maintained throughout the longitudinal direction of the cable and variation in impedance to be suppressed more effectively throughout the longitudinal direction of the cable.

The shield 606 is constructed from a braided magnetic shield formed by braiding the magnetic shielding strands 100 (or the magnetic shielding strands 200), or a served magnetic shield formed by winding the magnetic shielding strands 100 (or the magnetic shielding strands 200).

The sheath 607 is formed of any one of a polyvinyl chloride resin, a polyurethane resin or a halogen-free polyolefin resin. Use of such highly pliable or flexible materials to form the sheath 607 increases pliability or flexibility of the magnetic shielded cable 600, thereby allowing flex resistance of the magnetic shielded cable 600 to be improved.

The magnetic shielded cable 600, which is provided with a braided magnetic shield or a served magnetic shield formed using the magnetic shielding strands 100 (or the magnetic shielding strands 200), can achieve magnetic shielding performance and electromagnetic shielding performance throughout the entire length without impairment in flexibility or flex resistance required for cables to be wired in moving parts.

Next, a magnetic shielded cable in the seventh embodiment will be described.

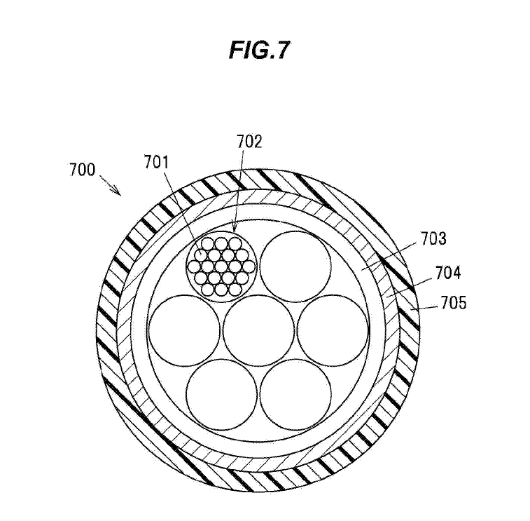

As shown in FIG. 7, a magnetic shielded cable 700 in the seventh embodiment is a probe cable and is provided with plural core wire units 702 each formed by twisting plural signal lines 701 together, a binding tape 703 wound around the core wire units 702, a shield 704 provided around the binding tape 703, and a sheath 705 covering around the shield 704.

The binding tape 703 is a resin tape for bundling the plural core wire units 702 and is, e.g., a polytetrafluoroethylene (PTFE) resin tape.

The sheath 705 is formed of a medical insulating resin. The medical insulating resin, also called medical resin or medical grade resin, is a biocompatible (highly biologically compatible) resin which is non-toxic and does not cause allergic symptoms such as inflammation upon contact with living body. In the seventh embodiment, a medical grade polyvinyl chloride (PVC) resin is used as the medical insulating resin to form the sheath 705.

The shield 704 is constructed from a braided magnetic shield formed by braiding the magnetic shielding strands 100 (or the magnetic shielding strands 200), or a served magnetic shield formed by winding the magnetic shielding strands 100 (or the magnetic shielding strands 200).

The magnetic shielded cable 700, which is provided with a braided magnetic shield or a served magnetic shield formed using the magnetic shielding strands 100 (or the magnetic shielding strands 200), can achieve magnetic shielding performance and electromagnetic shielding performance throughout the entire length without impairment in flexibility or flex resistance required for probe cables.

As describe above, the invention can provide a magnetic shielding strand as a material of a magnetic shield used to manufacture a magnetic shielded cable in which flexibility or flex resistance is less likely to be impaired, and also can provide a method of manufacturing such a magnetic shielding strand, and a magnetic-shielding braided sleeve and a magnetic shielded cable which use the magnetic shielding strand.

What is claimed is:

1. A magnetic shielding strand, comprising:
a conductor strand; and
a magnetic shielding layer formed around the conductor strand,
wherein the magnetic shielding layer comprises coating film layers and a magnetic powder layer sandwiched between the coating film layers.

2. The magnetic shielding strand according to claim 1, wherein the magnetic powder layer comprises a nanocrystalline soft magnetic material, and
the coating film layer comprises a UV curable resin coating material or a thermosetting resin coating material.

3. The magnetic shielding strand according to claim 1, wherein the magnetic shielding layer comprises a plurality of magnetic shielding layers each of which comprises the coating film layers and the magnetic powder layer sandwiched between the coating film layers.

4. A method of manufacturing the magnetic shielding strand according to claim 1, comprising:
a first step of forming an uncured coating film layer by applying a coating material around the conductor strand;
a second step of forming the magnetic powder layer by applying magnetic powder so as to be attached to the uncured coating film layer;
a third step of forming another uncured coating film layer by applying a coating material around the magnetic powder layer; and
a fourth step of curing all the uncured coating film layers to obtain the coating film layers.

5. The method according to claim 4, wherein the second and third steps are repeated.

6. A magnetic-shielding braided sleeve, comprising the magnetic shielding strand according to claim 1 that is braided.

7. A magnetic-shielding braided sleeve, comprising the magnetic shielding strand according to claim 1 and spun rayon yarns that are braided.

8. A magnetic shielded cable, comprising a braided magnetic shield formed by braiding the magnetic shielding strand according to claim 1, or a served magnetic shield formed by winding the magnetic shielding strand according to claim 1.
